(19) United States
(12) Patent Application Publication
(10) Pub. No.: US 2025/0133874 A1
(43) Pub. Date: Apr. 24, 2025

(54) GALLIUM NITRIDE-BASED SEMICONDUCTOR DEVICE ON AMORPHOUS SUBSTRATE AND METHOD FOR MANUFACTURING THE SAME

(71) Applicant: Japan Display Inc., Tokyo (JP)

(72) Inventors: Ryo ONODERA, Tokyo (JP); Masumi NISHIMURA, Tokyo (JP)

(73) Assignee: Japan Display Inc., Minato-ku, Tokyo (JP)

(21) Appl. No.: 18/989,284

(22) Filed: Dec. 20, 2024

Related U.S. Application Data
(63) Continuation of application No. PCT/JP2023/020439, filed on Jun. 1, 2023.

(30) Foreign Application Priority Data
Jun. 21, 2022 (JP) 2022-099824

(51) Int. Cl. H10H 20/825; H10H 20/01; H10H 20/817; H10H 20/831

(52) U.S. Cl. CPC H10H 20/825; H10H 20/0137; H10H 20/817; H10H 20/8312

(57) ABSTRACT

A gallium nitride-based semiconductor device includes an amorphous substrate, an orientation control layer on the amorphous substrate, a gallium nitride-based semiconductor layer on the orientation control layer, and at least one electrode in contact with the gallium nitride-based semiconductor layer. The at least one electrode is formed on the gallium nitride-based semiconductor layer by vacuum evaporation using a resistance heating evaporation source as a metallic material as a vapor deposition material.

### CROSS REFERENCE TO RELATED APPLICATIONS

This application is a Continuation of International Patent Application No. PCT/JP2023/020439, filed on Jun. 1, 2023, which claims the benefit of priority to Japanese Patent Application No. 2022-099824, filed on Jun. 21, 2022, the entire contents of which are incorporated herein by reference.

### FIELD

An embodiment of the present invention relates to an electrode structure for a gallium nitride-based semiconductor device including a gallium nitride-based semiconductor layer on an amorphous substrate and a method for manufacturing the same.

### BACKGROUND

A gallium nitride-based compound semiconductor light-emitting diode formed by vapor-phase growth of a gallium nitride-based compound semiconductor on a crystalline sapphire substrate by the metal organic chemical vapor deposition (MOCVD) method is known. The gallium nitride-based compound semiconductor light-emitting diodes formed on the sapphire substrate emit blue light, have high conversion efficiency and a long life, and are widely used in practical applications. However, the sapphire substrate is expensive, and a large area is not easy to achieve. Therefore, research is underway to fabricate gallium nitride-based compound semiconductors with crystallinity on an amorphous substrate.

To fabricate devices using gallium nitride-based semiconductor layers prepared by the sputtering method, electrodes that form contacts with the gallium nitride-based semiconductor layers are required. When electrodes are fabricated by the sputtering method, device characteristics may be affected due to damage caused during film deposition. When the gallium nitride-based semiconductor layer is damaged, it may become n-type due to a decrease in crystallinity or the creation of defects.

### SUMMARY

A gallium nitride-based semiconductor device in an embodiment according to the present invention includes an amorphous substrate, an orientation control layer on the amorphous substrate, a gallium nitride-based semiconductor layer on the orientation control layer, and at least one electrode in contact with the gallium nitride-based semiconductor layer. The at least one electrode is formed on the gallium nitride-based semiconductor layer by vacuum evaporation using a resistance heating evaporation source as a metallic material as a vapor deposition material.

A method for manufacturing a gallium nitride-based semiconductor device in an embodiment according to the present invention includes forming an orientation control layer on an amorphous substrate, forming a gallium nitride-based semiconductor layer on the orientation control layer, forming at least one electrode on the gallium nitride-based semiconductor layer, and forming the at least one electrode on the gallium nitride-based semiconductor layer by a vacuum evaporation method using a resistance heating evaporation source with a metallic material as the evaporation material.

### BRIEF DESCRIPTION OF DRAWINGS

FIG. 1 is a cross-sectional view showing the structure of a gallium nitride-based semiconductor device according to an embodiment of the present invention.

FIG. 2A is a cross-sectional structure of a diode as an example of a gallium nitride-based semiconductor device according to an embodiment of the present invention.

FIG. 2B is a cross-sectional structure of a diode as an example of a gallium nitride-based semiconductor device according to an embodiment of the present invention.

FIG. 3A is a cross-sectional structure of a light-emitting diode as an example of a gallium nitride-based semiconductor device according to an embodiment of the present invention.

FIG. 3B is a cross-sectional structure of a light-emitting diode as an example of a gallium nitride-based semiconductor device according to an embodiment of the present invention.

FIG. 4A is a cross-sectional structure of a transistor as an example of a gallium nitride-based semiconductor device according to an embodiment of the present invention.

FIG. 4B is a cross-sectional structure of a transistor as an example of a gallium nitride-based semiconductor device according to an embodiment of the present invention.

FIG. 5 is a graph showing a current-voltage characteristic of samples for which an upper electrode was fabricated by vapor deposition and sputtering methods.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by a, b, etc.) and a detailed description may be omitted as appropriate. The terms “first” and “second” appended to each element are a convenience sign used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

A gallium nitride-based semiconductor device according to an embodiment of the present invention will be described in detail below. As used herein, the term “gallium nitride-based semiconductor device” refers to a semiconductor device including a gallium nitride layer formed on an amorphous substrate and configured to exhibit a predetermined function. The gallium nitride-based semiconductor devices may include a light-emitting device such as a light-emitting diode and an active device such as a transistor. Examples of gallium nitride-based semiconductor devices include diodes, transistors, thyristors, light-emitting devices, light receiving devices, high frequency diodes, high frequency transistors, various sensors (temperature sensors, pressure sensors, acceleration sensors, and the like), integrated circuits, and other types of semiconductor devices. A gallium nitride-based semiconductor layer refers to a single or multilayer structure of at least one gallium nitride-based semiconductor layer, includes a structure in which a plurality of gallium nitride layers of different conductive types are stacked, and a structure in which not only gallium nitride but also layers of III-V compound semiconductors of different compositions, in which indium, aluminum, or other specified elements are added to gallium nitride, are stacked.

### 1. Basic Structure

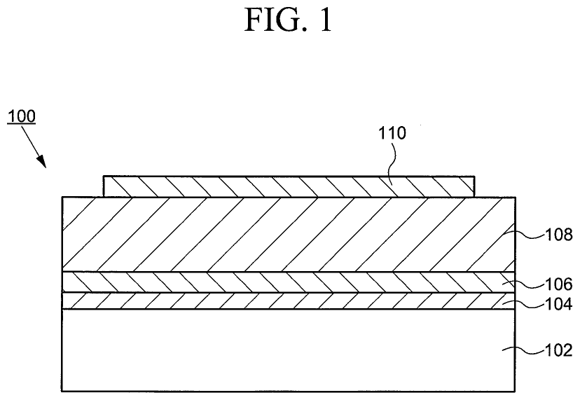

FIG. 1 shows an example of a cross-sectional structure of a gallium nitride-based semiconductor device 100 according to an embodiment of the present invention. The gallium nitride-based semiconductor device 100 has a structure in which an orientation control layer 106, a gallium nitride-based semiconductor layer 108, and an upper electrode 110 are stacked on an amorphous substrate 102. The gallium nitride-based semiconductor layer 108 is disposed on top of the orientation control layer 106, and the upper electrode 110 is disposed on top of the gallium nitride-based semiconductor layer 108. An underlying insulation layer 104 may be disposed between the amorphous substrate 102 and the orientation control layer 106.

The orientation control layer 106 is disposed to allow the gallium nitride-based semiconductor layer 108 to form a crystalline structure on the amorphous substrate 102. The gallium nitride-based semiconductor layer 108 is used as an active layer to express the functions of the gallium nitride-based semiconductor device 100. The upper electrode 110 is disposed to apply voltage to the gallium nitride-based semiconductor layer 108 and to allow current to flow through it. The active layer refers to a layer in which electrons and holes flow under the effect of an internal or external electric field to express the prescribed functions of the device, such as rectification, switching, amplification, photoelectric conversion, and luminescence. For example, as active layers, the layers that form the channel region, source region, and drain region in a transistor, the light-emitting layer in a light-emitting device, and a p-n junction or a Schottky junction in a diode are examples. Next, the details of each component configuring the gallium nitride-based semiconductor device 100 will be described.

### 1-1. Amorphous Substrate

The amorphous substrate 102 is a substrate formed of a material that does not have a crystalline structure. In other words, the amorphous substrate 102 is a substrate formed of an amorphous material. The amorphous substrate 102 preferably has an expansion coefficient smaller than 50×10⁻⁷/° C. and a strain point of 600° C. or higher. As an example of the amorphous substrate 102, a glass substrate is applicable. The glass substrate used as the amorphous substrate 102 is preferably an alkali metal such as sodium (Na) with a content of 0.1% or less. For example, the glass substrates formed of aluminoborosilicate glass and aluminosilicate glass are used as such glass substrates. Such glass substrates are used in liquid crystal displays and organic electroluminescence (Organic EL) displays, and large-area glass substrates, called mother glass, are available in the market. By selecting glass substrates as the amorphous substrate 102, gallium nitride-based semiconductor devices can be fabricated using large-area glass substrates.

The amorphous substrate 102 is preferably heat resistant to about 600° C., but it is not necessary to have a heat resistance of 1000° C. or higher, as is the case with sapphire substrates. The gallium nitride-based semiconductor layer 108 is deposited by the sputtering method. Previously, the metal organic chemical vapor deposition (MOCVD) method has been used to deposit gallium nitride films. The MOCVD method can deposit gallium nitride films with excellent crystallinity but requires a substrate temperature of 1,000° C. or higher during deposition. In contrast, it is possible to fabricate a gallium nitride-based semiconductor layer 108 with crystallinity at a substrate temperature of 600° C. or lower, e.g., 400° C. or lower, by applying the substrate structure shown in this embodiment by the sputtering method. Therefore, it is possible to use a flexible resin substrate such as a polyimide substrate, acrylic substrate, siloxane substrate, fluoropolymer substrate, or the like as the amorphous substrate 102, in addition to a glass substrate.

### 1-2. Underlying Insulation Layer

As shown in FIG. 1, the underlying insulation layer 104 may be disposed on top of the amorphous substrate 102 as an additional configuration. The underlying insulation layer 104 has a single-layer or multilayer structure. A silicon nitride film, silicon oxide film, silicon oxynitride film, aluminum nitride film, aluminum oxide film, aluminum oxynitride film, and the like are examples of inorganic insulating films that form the underlying insulation layer 104. Although not shown in FIG. 1 in detail, the underlying insulation layer 104 may have a two-layer structure. For example, the underlying insulation layer 104 may have a structure in which a silicon nitride film and a silicon oxide film are stacked in order from the amorphous substrate 102 side. In this structure, the silicon nitride film is preferably, for example, between 20 nm and 500 nm thick, and the silicon oxide film is preferably, for example, between 20 nm and 500 nm thick.

In order to fabricate high-quality gallium nitride-based semiconductor layers 108, it is necessary to reduce the concentration of contained impurities. For example, when a glass substrate is used as the amorphous substrate 102, there is concern regarding contamination of the gallium nitride-based semiconductor layer 108 by alkali metals because the glass substrate contains a small amount of alkali metals (such as sodium). Therefore, by arranging the underlying insulation layer 104 on the lower side of the gallium nitride-based semiconductor layer 108, it is possible to prevent the diffusion of alkali metals and prevent impurity contamination. For example, the silicon nitride film used as the underlying insulation layer 104 has a thickness of 20 nm or more to prevent diffusion of alkali metals from the amorphous substrate 102 to the gallium nitride-based semiconductor layer 108.

The underlying insulation layer 104 has the function of improving the adhesion of the orientation control layer 106 that is formed on top of it. For example, when the orientation control layer 106 is formed from a metal material, the use of an underlying insulation layer 104 with a film thickness of 20 nm or more, such as an oxide silicon film, can prevent the orientation control layer 106 from peeling off. In this way, by providing the underlying insulation layer 104 with both a barrier layer function against impurities and a layer function for improving the adhesion to the orientation control layer 106, it becomes possible to fabricate a gallium nitride-based semiconductor layer 108 with excellent crystallinity and high quality.

### 1-3. Orientation Control Layer

The orientation control layer 106 is formed on the amorphous substrate 102. The orientation control layer 106 has a crystalline structure. The crystalline structure of the orientation control layer 106 is preferably c-axis oriented. In other words, the orientation control layer 106 is preferably a c-axis orientation film. The crystalline structure of the orientation control layer 106 is preferably rotationally symmetric, for example, the crystalline surface is preferably six-fold symmetric. The crystalline structure of the orientation control layer 106 is preferably a hexagonal close-packed structure, a face-centered cubic structure, or a structure equivalent to these. Here, a structure similar to the hexagonal close-packed structure or the face-centered cubic structure includes a crystal structure in which the c-axis is not 90 degrees to the a-axis and b-axis. The orientation control layer 106, which has the hexagonal close-packed structure or a structure equivalent thereto, is preferably aligned in the (0001) direction, i.e., the c-axis direction, with respect to the first surface (the surface on which the gallium nitride-based semiconductor layer 108 is formed) of the amorphous substrate 102 (this alignment state is also referred to as the (0001) orientation of the hexagonal close-packed structure). In addition, the orientation control layer 106, which has the face-centered cubic structure or a structure equivalent to this, is preferably aligned in the (111) direction with respect to the first surface of the amorphous substrate 102 (this orientation is also referred to as the (111) orientation of the face-centered cubic structure).

There is a lattice mismatch between the amorphous substrate 102 and the gallium nitride-based semiconductor layer 108. Therefore, it is not possible to form a gallium nitride-based semiconductor layer 108 with excellent crystallinity directly on the amorphous substrate 102. However, by providing an orientation control layer 106 on the amorphous substrate 102, the lattice mismatch can be relaxed and the gallium nitride-based semiconductor layer 108 with high-quality crystallinity can be fabricated. The orientation control layer 106 has a crystal structure with c-axis alignment, which allows the gallium nitride-based semiconductor layer 108 to be crystallized. In other words, the orientation control layer 106 has the c-axis orientation and the crystalline surface having six-fold rotational symmetry, such as the hexagonal closest structure or face-centered cubic structure, so that the orientation can be controlled so that the c-axis of the gallium nitride-based semiconductor layer 108 grows in the film thickness direction (perpendicular to the principal surface of the amorphous substrate 102).

The orientation control layer 106 is preferably flat on the surface. The flatness of the orientation control layer 106 is expressed in terms of arithmetic mean roughness (Ra), and Ra is preferably smaller than 2.5 nm, and more preferably smaller than 2.3 nm. The arithmetic mean roughness (Ra) is a value measured by an atomic force microscope (AFM). The crystalline of the gallium nitride-based semiconductor layer 108 can be enhanced by the orientation control layer 106 having a flat surface.

The film thickness of the orientation control layer 106 is preferably 5 nm or more and 500 nm or less, and more preferably 10 nm or more and 200 nm or less. The film thickness can be measured with a contact step meter, an optical film thickness meter (ellipsometry), or from images obtained by a scanning electron microscope (SEM) or transmission electron microscope (TEM). It is possible for the orientation control layer 106 to have a flat surface while having crystals aligned on the c-axis by having a film thickness in this range.

The orientation control layer 106 is formed of a metallic material or an insulating material. Titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, SrFeO, BiFeO, BaFeO, or PMnN-PZT may be used as the metal material for forming the orientation control layer 106. As an insulating material for forming the orientation control layer 106, aluminum nitride (AIN), aluminum oxide (Al₂O₃), lithium niobate (LiNbO), BiLaTiO, SrFeO, SrFeO, BiFeO, BaFeO, ZnFeO, PMnN-PZT, or biological apatite (BAp) is preferably used. The orientation control layer 106 can be formed by sputtering using these metallic materials or insulating materials.

### 1-4. Gallium Nitride-Based Semiconductor Layer

The gallium nitride-based semiconductor layer 108 includes at least one gallium nitride (GaN) layer. For example, the gallium nitride-based semiconductor layer 108 is formed of a single layer of gallium nitride. The gallium nitride-based semiconductor layer 108 has a structure including at least one gallium nitride layer, and further includes at least one layer selected from an indium gallium nitride (InGaN) layer and an aluminum gallium nitride (AlGaN) layer, and these layers are stacked. The gallium nitride layer, indium gallium nitride layer, and aluminum gallium nitride layer forming the gallium nitride-based semiconductor layer 108 are preferably stoichiometric in composition but may deviate from a stoichiometric composition.

The gallium nitride-based semiconductor layer 108 is preferably crystalline. The gallium nitride layer forming the gallium nitride-based semiconductor layer 108 is preferably crystalline. The gallium nitride layer is preferably single crystalline, but may be polycrystalline, microcrystalline, or nanocrystalline. The crystalline structure of the gallium nitride layer is preferably a wurtzite structure. The gallium nitride layer configured in the gallium nitride-based semiconductor layer 108 is preferably aligned with a c-axis orientation or (111) alignment.

The conductive type of the gallium nitride layer forming at least one layer or all the layers of the gallium nitride-based semiconductor layer 108 may be substantially intrinsic or may have an n-type or p-type conductivity. The gallium nitride layer may contain dopants for valence control. The n-type gallium nitride layer may be doped with an element selected from silicon (Si) or germanium (Ge) as a dopant. The p-type gallium nitride layer may be doped with one element selected from magnesium (Mg), zinc (Zn), cadmium (Cd), and beryllium (Be) as a dopant. The n-type gallium nitride layer preferably includes a carrier concentration of 1×10¹⁸/cm³ or more. The p-type gallium nitride layer preferably includes a carrier concentration of 5×10¹⁶/cm³ or more. The substantially intrinsic (In other words, high-resistance) gallium nitride layer may include zinc (Zn) as a dopant.

The gallium nitride-based semiconductor layer 108 is in contact with the orientation control layer 106. When the gallium nitride-based semiconductor layer 108 includes the gallium nitride layer, it is preferable that the gallium nitride layer is in contact with the orientation control layer 106. The c-axis-oriented or (111)-oriented gallium nitride layer can be obtained by providing the orientation control layer 106 with a crystal structure having a c-axis orientation. The gallium nitride layer may include an amorphous structure in the vicinity of the interface with the orientation control layer 106, but it is preferable that the region (bulk) away from the interface has a crystalline structure. The gallium nitride layer having a crystalline structure makes it possible for the gallium indium nitride layer and the gallium aluminum nitride layer stacked on top of it to also have a crystalline structure. It is possible to enhance the performance of the gallium nitride-based semiconductor device 100 by providing each layer that makes up the gallium nitride-based semiconductor layer 108 with a crystalline structure. For example, when the gallium nitride-based semiconductor device 100 is a light-emitting device, the light-emitting intensity can be increased. When the gallium nitride-based semiconductor device 100 is an active device such as a transistor, the carrier mobility can be increased.

When gallium nitride films that configure the gallium nitride-based semiconductor layer 108 are deposited using the sputtering method, the substrate temperature (set temperature) during deposition is controlled to be in the range from room temperature to 600° C. Since the orientation control layer 106 is arranged as an underlayer of the gallium nitride layer, it is possible to deposit a gallium nitride layer with crystallinity even when the substrate temperature is 600° C. or less. The term “room temperature” refers to the state in which the substrate is set in the sputtering apparatus and is not intentionally heated or cooled. In this case, room temperature is 25° C., and the range of ±10° C. may be included.

A gallium nitride sintered compact is used as sputtering targets for the production of gallium nitride layers using the sputtering method. The gas (sputtering gas) used during the sputtering deposition process is argon (Ar) or a mixture of argon (Ar) and nitrogen (N₂). As a sputtering apparatus, it is possible to use a two-electrode sputtering apparatus, a magnetron sputtering apparatus, a dual magnetron sputtering apparatus, a counter target sputtering apparatus, an ion beam sputtering apparatus, and an inductively coupled plasma (ICP) sputtering apparatus.

There is no limitation on the thickness of the gallium nitride-based semiconductor layer 108, which is deposited using the sputtering method, and it is set appropriately according to the device structure. When layers having different compositions such as a gallium nitride layer, an indium gallium nitride layer, and an aluminum gallium nitride layer are laminated as the gallium nitride-based semiconductor layer 108, a sputtering target having different compositions is used, and by using a multi-chamber type sputtering apparatus, a continuous film can be formed in a vacuum.

### 1-5. Upper Electrode

The upper electrode 110 is arranged on the upper surface of the gallium nitride-based semiconductor layer 108. The upper electrode 110 has the function of an electrode for the gallium nitride-based semiconductor device 100. The upper electrode 110 is arranged to form a Schottky junction with the gallium nitride-based semiconductor layer 108. The upper electrode 110 is arranged to make an ohmic contact with the gallium nitride-based semiconductor layer 108.

In this embodiment, the upper electrode 110 is fabricated using the vacuum evaporation method. The vacuum evaporation method is a technique for forming a thin film by heating a metal or other evaporation material in a vacuum, causing it to evaporate or sublime, and then depositing the evaporated or sublimed particles (atoms or molecules) on the surface of a substrate. The evaporation material is heated in an evaporation source placed in a vacuum. The known evaporation sources are the resistance heating evaporation source, the high-frequency induction heating evaporation source, and the electron beam evaporation source. The metal film forming the upper electrode 110 can be formed by any of these three types of evaporation source, but in this embodiment, the resistance heating evaporation source is used. In other words, in this embodiment, the upper electrode 110 is deposited using a deposition method that does not use charged particles such as ion and electron beams. A high-frequency induction heating evaporation source may be used as the evaporation source. The vacuum deposition method is performed at a vacuum level of 10⁻⁴ to 10⁻⁵ Pa, with a film deposition rate in the range of 0.1 to 1 nm/sec. The substrate temperature is maintained at room temperature but may be heated to 50 to 200° C. as necessary. It is possible to prevent damage (defects) to the gallium nitride-based semiconductor layer 108 by fabricating the upper electrode 110 using a vacuum deposition method with a resistance heating evaporation source, and it is possible to form a good metal/semiconductor interface. There is a problem with sputtering methods in that internal stress can remain in the film due to sputtering gas being mixed in, but this problem does not occur with vacuum deposition methods. Therefore, it is possible to prevent internal stress from remaining in the upper electrode 110, and to reduce the internal stress remaining in the gallium nitride-based semiconductor device 100.

The upper electrode 110 is fabricated using a metal material (conductive material) that can be vacuum-deposited using a resistance heating evaporation source. For example, aluminum (Al), gold (Au), or silver (Ag) can be used as a metal material (conductive material). The upper electrode 110 is formed using such a metal material (conductive material) to a thickness of 100 nm to 200 nm.

Compared to the sputtering method, the vacuum deposition method causes less damage to the deposition surface because the energy of the particles that travel is smaller. Among vacuum deposition methods, when a resistance heating evaporation source is used, there is no generation of charged particles such as ion or electron beams in principle. Therefore, it is possible to deposit a metal film with almost no damage to the deposition surface. An electron beam evaporation source is a method that heats the deposition material by irradiating it with an electron beam, but the reflected electrons generated during the irradiation can cause damage to the deposition surface and may even cause a rise in temperature. Similarly, the ion plating method, which involves direct current or high-frequency discharge, is a concern because the energy of the particles that travel to the deposition surface is relatively high, and ions and electrons are generated in the deposition space. Therefore, there is a concern regarding damage to the deposition surface. For this reason, in this embodiment, the upper electrode 110 is fabricated using a vacuum deposition method that uses a resistance heating evaporation source or an induction heating evaporation source, which does not involve the action of charged particles such as ion and electron beams, thereby reducing damage to the gallium nitride-based semiconductor layer 108 and enabling good device characteristics to be obtained. Since the upper electrode 110 is formed using a vacuum deposition method with a resistance heating evaporation source, even if it is formed to overlap with the orientation control layer 106, which has conductive properties through the gallium nitride-based semiconductor layer 108, damage to the underlying layer is reduced during film formation, and short circuits can be prevented.

In order to reduce damage to the gallium nitride-based semiconductor layer 108, which forms an underlying layer, and to reduce internal stress of the upper electrode 110, it is preferable that the entire upper electrode 110 is fabricated by a vacuum evaporation method using a resistance heating evaporation source. The upper electrode 110 is formed with a single layer structure. The upper electrode 110 may also have a laminated structure made of different metals, using a vacuum deposition method with a resistance heating evaporation source.

As shown in FIG. 1, the gallium nitride-based semiconductor device 100 can be made to function as a device that applies voltage to or allows current to flow through the gallium nitride-based semiconductor layer 108 by using the orientation control layer 106 and the upper electrode 110 as electrodes. FIG. 1 does not show the details of the gallium nitride-based semiconductor layer 108, but various devices can be realized by using a configuration that includes a metal/semiconductor junction or a semiconductor junction. The following illustrates some of the specific configurations of the gallium nitride-based semiconductor device 100 of this embodiment.

### 2-1. Diode

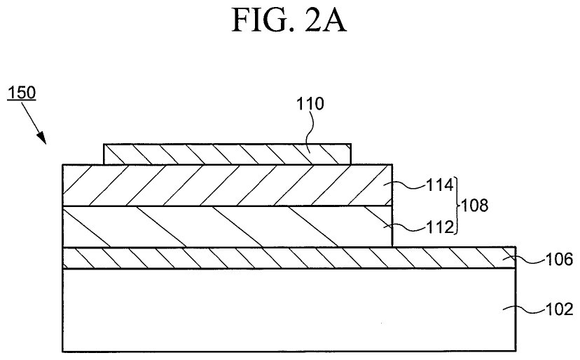

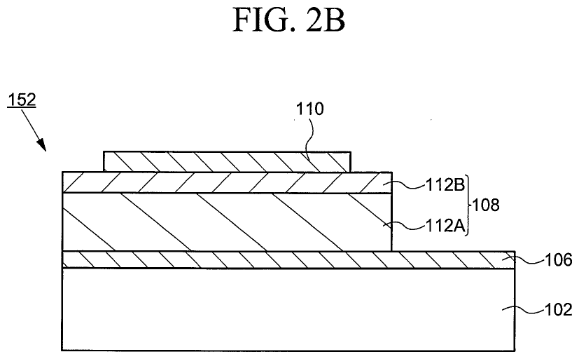

FIG. 2A shows a p-n junction diode 150 fabricated using gallium nitride as an example of a gallium nitride-based semiconductor device. The p-n junction diode 150 has a structure in which an orientation control layer 106, a gallium nitride-based semiconductor layer 108, and an upper electrode 110 are stacked on an amorphous substrate 102. The gallium nitride-based semiconductor layer 108 has a structure in which an n-type gallium nitride layer 112 and a p-type gallium nitride layer 114 are laminated.

The orientation control layer 106 is fabricated from a metal material. The orientation control layer 106 is fabricated from a metal material such as titanium (Ti), nickel (Ni), aluminum (Al), and the like. The orientation control layer 106 is fabricated using a sputtering method with such a metal material. In the structure shown in FIG. 2A, the orientation control layer 106 has electrical conductivity, and therefore can also function as the lower electrode of the p-n junction diode 150. In other words, the orientation control layer 106 is used as the lower electrode that makes ohmic contact with the n-type gallium nitride layer 112. By adding a type of element selected from silicon (Si) or Germanium (Ge) as an n-type dopant to the n-type gallium nitride layer 112 to reduce its resistance, it is possible to form good ohmic contact with the orientation control layer 106, which is used as the lower electrode.

Although not shown in FIG. 2A, another device structure of the p-n junction diode 150 may include a drift layer formed by stacking a high resistivity n-type gallium nitride layer on top of an n-type gallium nitride layer 112 with low resistivity. FIG. 2A shows a structure in which the n-type gallium nitride layer 112 and p-type gallium nitride layer 114 are laminated sequentially from the orientation control layer 106 side, but the laminating order of these layers may be reversed.

The upper electrode 110 is fabricated using a vacuum deposition method with a resistance heating evaporation source using metallic materials such as nickel (Ni), gold (Au), platinum (Pt), and palladium (Pd). There is no limitation on the thickness of the upper electrode 110, and may be formed with a thickness of 100 nm to 500 nm, for example. The upper electrode 110 may have a laminated structure (for example, Pd/Au, Ni/Au, and so on) using the metal materials listed above.

It is possible to reduce damage to the p-type gallium nitride layer 114 by fabricating the upper electrode 110 using a vacuum deposition method with a resistance heating evaporation source. Therefore, donor-type defects and deep defect levels that act as carrier capture centers are not formed in the p-type gallium nitride layer 114, and the increase in resistance of the p-type gallium nitride layer 114 can be suppressed. As a result, an upper electrode 110 that forms an ohmic contact in good condition on the surface of the p-type gallium nitride layer 114 can be arranged. It is possible to prevent the upper electrode 110 from shorting with the orientation control layer 106, which is used as the lower electrode.

FIG. 2B shows a Schottky barrier diode 152 fabricated with gallium nitride as an example of a gallium nitride-based semiconductor device. The structure of the Schottky barrier diode 152 has an orientation control layer 106, a gallium nitride-based semiconductor layer 108, and an upper electrode 110 laminated on an amorphous substrate 102. The gallium nitride-based semiconductor layer 108 has a structure in which a first n-type gallium nitride layer 112A and a second n-type gallium nitride layer 112B are stacked. The first n-type gallium nitride layer 112A and the second n-type gallium nitride layer 112B have different electrical conductivities. The first n-type gallium nitride layer 112A is a low-resistance layer that contains a high concentration of n-type dopants, and the second n-type gallium nitride layer 112B is a high-resistance layer that has n-type conductivity but a relatively high resistivity.

The second n-type gallium nitride layer 112B has low electrical conductivity. Therefore, it is formed relatively thin compared to the first n-type gallium nitride layer 112A. The second n-type gallium nitride layer 112B only needs to have a thickness of 100 nm or less, preferably 50 nm or less, as a Schottky junction is formed with the upper electrode 110.

The upper electrode 110 is formed of a metal material that forms a Schottky junction with the second n-type gallium nitride layer 112B. By using a metal material with a higher work function than the second n-type gallium nitride layer 112B to form the upper electrode 110, a Schottky junction can be formed. For example, aluminum (Al), gold (Au), and silver (Ag) have a higher work function than the second n-type gallium nitride layer 112B. Therefore, they can be used as the metal material to form the upper electrode 110.

The Schottky junction is sensitive to the state of the interface. Therefore, it is necessary to be careful about the manufacturing conditions. In this embodiment, the upper electrode 110 is formed using a vacuum deposition method with a resistance heating evaporation source, which forms a good Schottky junction with few interface levels. It is possible to obtain the Schottky barrier diode 152, which has a high breakdown voltage and good rectification characteristics.

FIG. 2A and FIG. 2B show a configuration without the underlying insulation layer 104, but the underlying insulation layer 104 may be arranged between the amorphous substrate 102 and the orientation control layer 106 in the same way as the configuration shown in FIG. 1.

### 2-2. Light-Emitting Devices

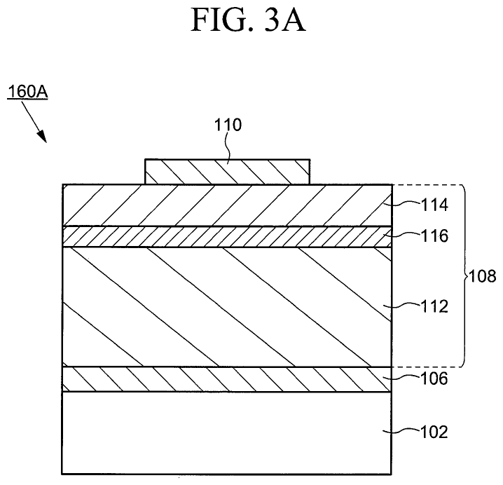

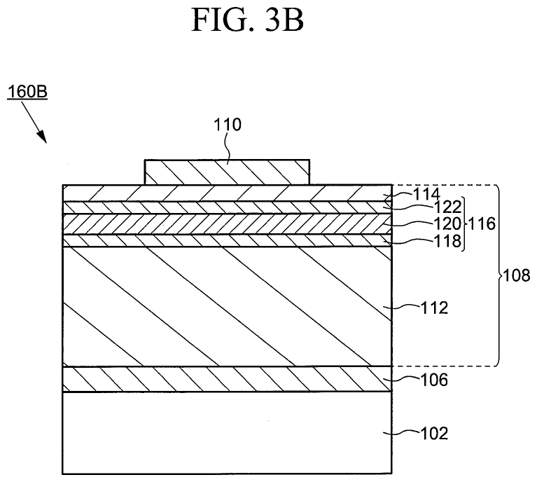

FIG. 3A shows a cross-sectional view of a light-emitting diode 160A as an example of a gallium nitride-based semiconductor device. The light-emitting diode 160A has a structure in which an orientation control layer 106 and a gallium nitride-based semiconductor layer 108 are stacked on an amorphous substrate 102.

The gallium nitride-based semiconductor layer 108 has a structure in which an n-type gallium nitride layer 112, a light-emission layer 116, and a p-type gallium nitride layer 114 are laminated. An upper electrode 110 is arranged on top of the p-type gallium nitride layer 114. The structure of the light-emitting layer 116 can be varied, and it may be formed by quantum well layers in which gallium nitride (GaN) layers and indium gallium nitride (InGaN) layers are alternately laminated.

FIG. 3B shows a cross-sectional view of an LED 160B, in which the configuration of the gallium nitride-based semiconductor layer 108 is different from that of FIG. 3A. The LED 160B has a structure in which an n-type gallium nitride layer 112, a light-emission layer 116, and a p-type gallium nitride layer 114 are stacked. The light-emitting layer 116 has a structure in which an n-type gallium aluminum nitride layer 118, an indium gallium nitride layer 120, and a p-type gallium aluminum nitride layer 122 are stacked. Since the composition of each of these layers forming the gallium nitride-based semiconductor layer 108 is different, they are fabricated using sputtering targets corresponding to each composition.

The light-emitting diode 160A shown in FIG. 3A and the light-emitting diode 160B shown in FIG. 3B are both fabricated using a vacuum deposition method with a resistance heating evaporation source for the upper electrode 110. The upper electrode 110 is fabricated from a metal material such as nickel (Ni), gold (Au), platinum (Pt), or palladium (Pd) using a vacuum deposition method with a resistance heating evaporation source. By fabricating the upper electrode 110 using a vacuum deposition method with a resistance heating evaporation source, damage to the p-type gallium nitride layer 114 can be prevented, and deep defect levels that act as donor-type defects and carrier capture centers cannot be formed, preventing the p-type gallium nitride layer 114 from becoming highly resistive. As a result, the upper electrode 110 can be made to make good ohmic contact with the p-type gallium nitride layer 114, and the series resistance component of the light-emitting diodes 160A and 160B can be reduced.

The orientation control layer 106, gallium nitride-based semiconductor layer 108, and upper electrode 110 that make up the light-emitting diodes 160A and 160B can be formed on the amorphous substrate 102 having a large-area using thin film fabrication methods such as sputtering and vacuum deposition. Since the light-emitting diodes 160A and 160B are small chips, the number of chips that can be separated from one sheet of the single amorphous substrate 102 can be increased, which improves productivity. An LED array can be made by arranging the light-emitting diode 106A or the light-emitting diode 106B on the amorphous substrate 102. In other words, it is possible to manufacture a display device in which the LED array is formed directly on the amorphous substrate 102.

### 2-3. Transistors

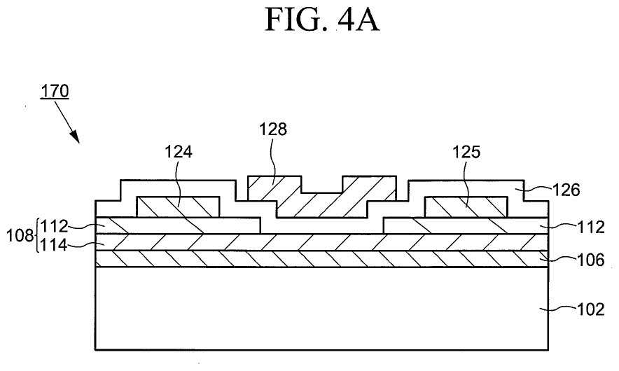

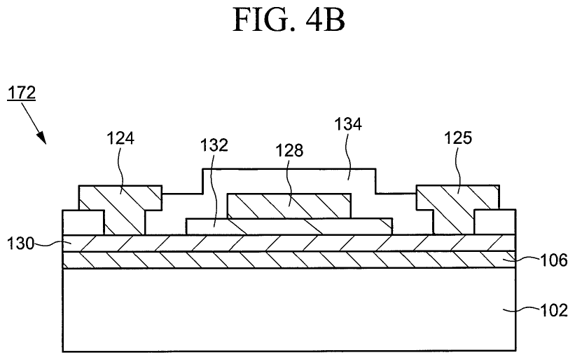

FIG. 4A shows a field-effect transistor 170, which is an example of a gallium nitride-based semiconductor device. The field-effect transistor 170 includes a gallium nitride-based semiconductor layer 108 formed on an amorphous substrate 102 via an orientation control layer 106. The gallium nitride-based semiconductor layer 108 includes a p-type gallium nitride layer 114 and an n-type gallium nitride layer 112. The n-type gallium nitride layer 112 is arranged in two regions to form a source region and a drain region on the p-type gallium nitride layer 114.

The source electrode 124 and drain electrode 125 are formed on the n-type gallium nitride layer 112. The source electrode 124 and drain electrode 125 are formed using a vacuum deposition method with a resistance heating evaporation source. The source electrode 124 and drain electrode 125 are formed from a metal material that can be vacuum deposited using a resistance heating evaporation source. For example, aluminum (Al), gold (Au), and silver (Ag) can be used as metal materials. By fabricating the source electrode 124 and drain electrode 125 using the vacuum evaporation method with a resistance heating evaporation source, it is possible to reduce damage to the n-type gallium nitride layer 112 and form good ohmic contact.

A gate insulating layer 126 is arranged to cover the p-type gallium nitride layer 114 and n-type gallium nitride layer 112. The gate insulating layer 126 is formed from an inorganic insulating material such as silicon oxide or silicon nitride. A gate electrode 128 is arranged above the gate insulating layer 126. The gate electrode 128 is arranged so that it overlaps the region where the n-type gallium nitride layer 112 forming the source and drain regions are separated. FIG. 4A shows an n-channel field-effect transistor 170 in which a channel region is formed in a p-type gallium nitride layer 114, but by switching the arrangement of the p-type gallium nitride layer 114 and the n-type gallium nitride layer 112, it can be made into a p-channel field-effect transistor.

FIG. 4B shows an example of a high electron mobility field-effect transistor (HEMT) 172. The high electron mobility field-effect transistor 172 has a layered structure consisting of an electron transport layer 130 formed from an undoped gallium nitride layer and an electron supply layer 132 formed from an n-type aluminum gallium nitride (AlGaN) layer.

The electron transport layer 130 and electron supply layer 132 are fabricated by sputtering on the orientation control layer 106. The source electrode 124 and drain electrode 125 are fabricated using a metal material that can be vacuum-deposited using a resistance heating evaporation source. For example, aluminum (Al), gold (Au), and silver (Ag) can be used as metal materials. By fabricating the source electrode 124 and drain electrode 125 using a vacuum deposition method with a resistance heating evaporation source, it is possible to reduce damage to the undoped gallium nitride layer that forms the electron transport layer 130 and form good ohmic contact. Although not shown in the figure, in order to reduce the contact resistance of the source electrode 124 and the drain electrode 125 to the electron transport layer 130, the n-type gallium aluminum nitride layer that forms the electron supply layer 132 may be extended to the region where the source electrode 124 and the drain electrode 125 are arranged. In other words, the source electrode 124 and drain electrode 125 may be in contact with the n-type aluminum gallium nitride (AlGaN).

A gate electrode 128 is arranged on the electron supply layer 132. The gate electrode 128 is formed in such a way as to form a Schottky barrier with the electron supply layer 132. For example, a Schottky barrier can be formed by using aluminum (Al), gold (Au), or silver (Ag), which have a larger work function than the n-type aluminum gallium nitride layer, as the metal to form the gate electrode 128. In such a structure, by fabricating the gate electrode 128 using the above-mentioned metal materials and a vacuum deposition method using a resistance heating evaporation source, it is possible to prevent damage during film formation and prevent defects from forming at the interface, and a good Schottky barrier can be formed.

When the gate electrode 128 forms a Schottky barrier with the electron supply layer 132, the entire electron supply layer 132 is depleted due to its thin formation. As a result, the high electron mobility field-effect transistor 172 does not form a channel in the electron supply layer 132, and the electrons accumulate in the potential well formed at the interface between the electron supply layer 132 and the electron transport layer 130, forming a thin channel region with two-dimensional electron gas. The concentration (carrier concentration) of the two-dimensional electron gas changes according to the voltage applied to the gate electrode 128. Therefore, when a positive bias voltage is applied to the drain electrode 125, the drain current can be changed according to the voltage applied to the gate electrode 128.

As described above, the characteristics of the high electron mobility field-effect transistor 172 are affected not only by the source electrode 124 and the drain electrode 125, but also by the contact between the gate electrode 128 and the electron supply layer 132 (n-type aluminum gallium nitride layer). In this embodiment, the gate electrode 128 is formed using a vacuum deposition method with a resistance heating evaporation source, which allows for the reproducible formation of a good Schottky contact with few interface defects. As a result, the variation in the characteristics of the high electron mobility field-effect transistor 172 is reduced, and a high field-effect mobility can be achieved.

As described above, according to this embodiment, by fabricating the electrode (upper electrode) in contact with the gallium nitride-based semiconductor layer using a resistance heating evaporation source, it is possible to reduce damage to the underlying layer and fabricate an electrode with good contact conditions. As a result, it is possible to stabilize the characteristics of various devices and improve the manufacturing yield.

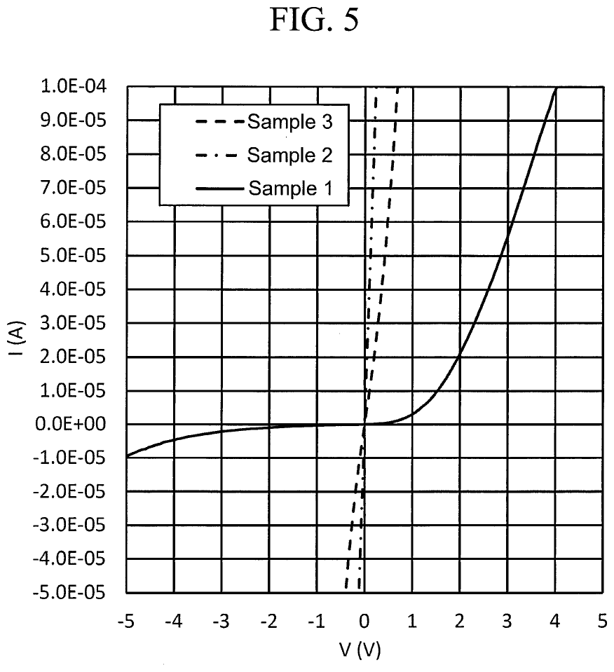

FIG. 5 shows a current-voltage characteristic of Samples 1, 2, and 3, which have a diode structure fabricated by a gallium nitride layer on an amorphous substrate 102. Samples 1, 2, and 3 have a structure similar to the layered structure shown in FIG. 2A. Specifically, a glass substrate is used as the amorphous substrate 102, and a titanium film is used as the orientation control layer 106 in Samples 1, 2, and 3. The gallium nitride layer on the orientation control layer 106 has a structure in which an n-type gallium nitride layer (corresponding to layer 112 in FIG. 2A) and a substantially intrinsic gallium nitride layer (corresponding to layer 114 in FIG. 2A) are stacked. The upper electrode 110 is made of an aluminum film. The term “substantially intrinsic gallium nitride layer” refers to a gallium nitride layer that has been intentionally fabricated without the addition of impurity elements for the purpose of controlling valence electrons, except for unavoidable impurity elements such as oxygen and carbon. This is referred to as an “intrinsic gallium nitride layer” below.

In Samples 1, 2 and 3, the thickness of the orientation control layer 106 is 100 nm, the thickness of the n-type gallium nitride layer 112 is 100 nm, the thickness of the i-type gallium nitride layer 114 is 50 nm, and the thickness of the upper electrode 110 is 100 nm. The orientation control layer 106, the n-type gallium nitride layer 112, and the i-type gallium nitride layer 114 were fabricated using the sputtering method, and the upper electrode 110 of Sample 1 was fabricated using the vacuum evaporation method with a resistance heating evaporation source. The deposition conditions for the upper electrode of Sample 1 were a vacuum pressure of 10⁻⁴ to 10⁻⁵ Pa, a substrate temperature of room temperature, and the use of aluminum as the metal material, with a deposition rate of 0.3 nm/sec to form a thickness of 100 nm.

FIG. 5 shows the characteristics of Sample 1, in which the upper electrode was fabricated using the vacuum deposition method, with a solid line, and the characteristics of Sample 2, in which the upper electrode 110 was fabricated using the sputtering method, with a dotted line. As shown in the graph in FIG. 5, Sample 1, in which the upper electrode 110 was fabricated using the vacuum deposition method, has good rectification characteristics, with current flowing in the forward bias voltage but not in the reverse bias voltage.

On the other hand, Sample 3 is a device with an ITO (indium-tin oxide) film made using the sputtering method as the upper electrode 110, and Sample 2 is a device with a MoW (molybdenum-tungsten) film made using the sputtering method as the upper electrode 110. The characteristics of Sample 2 and Sample 3 were the same as those of Sample 1, except for the conditions for fabricating the upper electrode, and they had the same structure.

As is clear from the characteristics shown in FIG. 5, Sample 2 and Sample 3 do not show rectification characteristics, and show a characteristic of linearly increasing current in both the forward and reverse bias states. This characteristic is thought to be due to the upper electrode and lower electrode being short-circuited or close to being short-circuited. The cause is thought to be due to the method used to fabricate the upper electrode. In other words, when the upper electrode is fabricated using the sputtering method, damage is caused to the lower gallium nitride layer (p-type gallium nitride layer, n-type gallium nitride layer), which is thought to cause a short-circuit with the lower electrode.

As shown in this example, it can be confirmed that the upper electrode is fabricated using a vacuum deposition method with a resistance heating evaporation source on top of the gallium nitride layer, and that this results in better characteristics than when the sputtering method is used.

What is claimed is:

1. A gallium nitride-based semiconductor device, comprising:
an amorphous substrate;
an orientation control layer on the amorphous substrate;
a gallium nitride-based semiconductor layer on the orientation control layer; and
at least one electrode in contact with the gallium nitride-based semiconductor layer,
wherein the at least one electrode is formed on the gallium nitride-based semiconductor layer by vacuum evaporation using a resistance heating evaporation source as a metallic material as a vapor deposition material.

2. The gallium nitride-based semiconductor device according to claim 1, wherein the at least one electrode is a single-layer of the metallic material, and the entire single-layer is formed by vacuum evaporation using the resistance heating evaporation source.

3. The gallium nitride-based semiconductor device according to claim 1, wherein the gallium nitride-based semiconductor layer is formed on the orientation control layer by a sputtering method using a gallium nitride-based sintered target and a substrate surface temperature ranging from room temperature to 600° C.

4. The gallium nitride-based semiconductor device according to claim 1, wherein the orientation control layer has conductive properties; and
the at least one electrode is arranged to overlap the orientation control layer with the gallium nitride-based semiconductor layer in between.

5. The gallium nitride-based semiconductor device according to claim 1, wherein the metallic material is one selected from aluminum (Al), gold (Au), and silver (Ag).

6. A method for manufacturing a gallium nitride-based semiconductor device, the method comprising:
forming an orientation control layer on an amorphous substrate;
forming a gallium nitride-based semiconductor layer on the orientation control layer;
forming at least one electrode on the gallium nitride-based semiconductor layer; and
forming the at least one electrode on the gallium nitride-based semiconductor layer by a vacuum evaporation method using a resistance heating evaporation source with a metallic material as an evaporation material.

7. The method according to claim 6, wherein the at least one electrode is a single-layer of the metallic material, and
the entire single-layer is formed using a vacuum deposition method with a resistance heating evaporation source.

8. The method according to claim 6, wherein the gallium nitride-based semiconductor layer is formed using a sputtering method with a gallium nitride-based sintered target and a substrate surface temperature ranging from room temperature to 600° C.

9. The method according to claim 6, wherein the orientation control layer is formed on the amorphous substrate using a metal target and a sputtering method.

10. The method according to claim 6, wherein the metallic material is one selected from aluminum (Al), gold (Au), and silver (Ag).
